(19) United States
(12) Patent Application Publication
(10) Pub. No.: US 2025/0254994 A1
(43) Pub. Date: Aug. 7, 2025

(54) ELECTRONIC DEVICE

(71) Applicant: InnoLux Corporation, Miao-Li County (TW)

(72) Inventors: Yuan-Lin Wu, Miao-Li County (TW); Kuan-Feng Lee, Miao-Li County (TW)

(73) Assignee: InnoLux Corporation, Miao-Li County (TW)

(21) Appl. No.: 19/011,659

(22) Filed: Jan. 7, 2025

(30) Foreign Application Priority Data
Feb. 2, 2024 (CN) 202410146572.4

(51) Int. Cl. H10D 86/40; H10D 86/60

(52) U.S. Cl. CPC H10D 86/411; H10D 86/60

(57) ABSTRACT

An electronic device includes a flexible substrate with a first region and a second region between the first region and an edge of the flexible substrate. A first electronic unit is disposed on the first region of the flexible substrate. A first driving circuit unit is electrically connected to the first electronic unit and disposed on the first region of the flexible substrate. The first electronic unit includes a plurality of first transistors. A second electronic unit is disposed on the second region of the flexible substrate. A second driving circuit unit is electrically connected to the second electronic unit and disposed on the second region of the flexible substrate. The second driving circuit unit includes a plurality of second transistors. A first arrangement of the plurality of first transistors is different from a second arrangement of the plurality of the second transistors.

### BACKGROUND OF THE DISCLOSURE

### 1. Field of the Disclosure

The disclosure relates to an electronic device, particularly to an electronic device having a corner display region.

### 2. Description of the Prior Art

With the advancement of technology, electronic devices equipped with display devices have become indispensable for human in modern life. However, current display devices are still unable to fulfill every expectation in various aspects. How to improve the display quality and production yield of the display devices as progressing to a higher resolution and smaller pixel areas is an important research topic in the field.

### SUMMARY OF THE DISCLOSURE

One aspect of this disclosure is to provide an electronic device having driving circuit units in the corner region designed in a manner to accommodate the stresses in different portions of the corner region, thereby reducing the adverse effects of stress on the performance or structure integrity of transistors of the circuit units.

In one embodiment of the disclosure, the electronic device includes a flexible substrate with a first region and a second region between the first region and an edge of the flexible substrate. A first electronic unit is disposed on the first region of the flexible substrate. A first driving circuit unit is electrically connected to the first electronic unit and disposed on the first region of the flexible substrate. The first electronic unit includes a plurality of first transistors. A second electronic unit is disposed on the second region of the flexible substrate. A second driving circuit unit is electrically connected to the second electronic unit and disposed on the second region of the flexible substrate. The second driving circuit unit includes a plurality of second transistors. A first arrangement of the plurality of first transistors is different from a second arrangement of the plurality of the second transistors.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

To facilitate understanding, the same reference numerals are used to indicate the same components shown in the drawings whenever possible. It can be expected that the components disclosed in one embodiment may be utilized in other embodiments without specific description. Unless otherwise specified, the drawings in this disclosure should not be understood as drawn to scale, and for the sake of clarity in expression and explanation, the drawings are often simplified and some details or components may be omitted. The drawings and descriptions in this document are used to explain the principles discussed below, with similar reference numerals indicating the same components.

FIG. 1 shows a schematic perspective view of an electronic device according to an embodiment of this disclosure on the left side, and a schematic plan view of the electronic device on the right side.

FIG. 2 is a schematic plan view of a partial area of the electronic device shown in FIG. 1.

FIG. 3 is an equivalent circuit diagram of the driving circuit unit and the electronic unit according to of an embodiment of the present disclosure.

FIG. 4 is a schematic plan view of a driving circuit unit according to an embodiment of the present disclosure.

FIG. 5 is a schematic layout of arrangement of the transistors of the first driving circuit unit according to an embodiment of the present disclosure on the left side, and a schematic layout of arrangement of the transistors of the second driving circuit unit according to an embodiment of the present disclosure on the right side.

FIG. 6 is a schematic plan view of a part of an electronic device according to an embodiment of the present disclosure.

FIG. 7 is a schematic plan view of a part of an electronic device according to an embodiment of the present disclosure.

FIG. 8 is a schematic plan view of a part of an electronic device according to an embodiment of the present disclosure.

FIG. 9 is a cross-sectional schematic diagram of an electronic device according to an embodiment of the present disclosure.

FIG. 10 is a schematic plan view of a part of an electronic device according to an embodiment of the present disclosure.

FIG. 11 is a schematic plan view of a part of an electronic device according to an embodiment of the present disclosure.

### DETAILED DESCRIPTION

To make this disclosure clearer and easier to understand, the following descriptions provide specific implementation examples and detailed explanations in conjunction with the attached drawings. It should be noted that, for the sake of simplicity in the drawings and to facilitate reader comprehension, some drawings in this disclosure only depict a portion of the electronic device. The quantity and size of the components in the drawings are merely illustrative and are not drawn to scale; they should not be interpreted as defining or limiting the scope or nature of the embodiments covered by these descriptions. For clarity, the relative sizes, thicknesses, and positions of the various layers, regions, and/or structures in the description may be exaggerated or reduced.

Certain terminology may be used in the disclosure and the claims to refer to specific components. Those skilled in the art should understand that electronic device manufacturers may refer to the same components by different names. This document is not intended to distinguish between components that have the same function but different names. In the following description and claims, terms such as “comprising”, “including”, and “having” are open-ended terms and should be interpreted as “including but not limited to”.

In this disclosure, when a component or layer is referred to as “on another component or layer” or “connected to another component or layer,” it may be directly on or directly connected to another component or layer, or may be indirectly on or indirectly connected to another component or layer with other components or layers present therebetween. On the contrary, when a component is referred to as “directly on another component or layer” or “directly connected to another component or layer,” there are no intervening components or layers disposed therebetween the. Additionally, when a component or layer is referred to as “on another component or layer”, it implies an upper-lower spatial relationship in the vertical direction, meaning that this component or layer may be above or below another component or layer, and this vertical relationship depends on the orientation of the device. The directional terms mentioned in this document, such as “up”, “down”, “front”, “back”, “left”, “right” etc., are referenced based on the directions in the accompanying drawings for illustrative purposes and are not intended to limit the scope of this disclosure.

In this disclosure, the terms “approximately”, “equal to”, or “similar” typically represent a range within 20% of a given value or range, or within 10%, 5%, 3%, 2%, 1%, or 0.5% of a given value or range. If the first direction is perpendicular to or “approximately” perpendicular to the second direction, the angle between the first and second directions may range from 80 degrees to 100 degrees. If the first direction is parallel to or “approximately” parallel to the second direction, the angle between the first and second directions may range from 0 degrees to 10 degrees.

In this disclosure, terms such as “first”, “second”, and “third” are used to describe or name different components, and these components are not limited to these terms. These terms are only used to distinguish one component from others in the specification, and are not related to the manufacturing order of these components. Different terminology may be used in the claims to name the components. In the claims, the terms “first”, “second”, “third”, or the like, may be used to name the components according to the declare order in the claims.

In this disclosure, the terms “soft”, “bendable”, or “flexible” refer to the ability to be bent, folded, stretched, flexed, or other similar deformations.

Unless otherwise defined, all terms used herein (including technical and scientific terms) have the same meanings as understood by those of ordinary skill in the field to which this disclosure pertains. It is understood that these terms, as defined in commonly used dictionaries, should be interpreted to have meanings consistent with the relevant technology and the background or context of this disclosure, and should not be interpreted in an over narrow or over formal manner, unless being specifically defined in the disclosure.

The electronic device provided in this disclosure may include a display device, a light-emitting device, an antenna, a sensing device, or other suitable devices, or a combination of the above devices, but is not limited thereto. The embodiments of the display device may include: non-self-luminous liquid crystal displays (LCD), light-emitting diode displays (LED Display), electro-phoretic displays (EPD), and various other types of displays that can present images and pictures, but are not limited thereto. The electronic device may include, for example, liquid crystals, fluorescence, phosphors, light-emitting diodes (LED), other suitable display media, or combinations thereof, but is not limited thereto. The light-emitting diodes may include, for example, self-luminous organic light-emitting diodes (OLED), inorganic light-emitting diodes, mini light-emitting diodes, micro light-emitting diodes, quantum dot diodes (QLED, QDLED), or a combinations thereof, but are not limited thereto. The electronic device disclosed herein may be used in architecture, automobiles, interior decoration, signage, display windows, or optical devices, but is not limited thereto.

Optical microscopes (OM), scanning electron microscopes (SEM), alpha-step film thickness profilers, ellipsometers, or other suitable methods may be used to measure the depth, thickness, width, or height of each component, or the spacing or distance between components of the display device. According to some embodiments, a scanning electron microscope (SEM) may be used to obtain the cross-sectional structural views of the components to be measured, and may be also used to measure the depths, thicknesses, widths, or heights of the components and the spacings or distances between components.

It should be noted that the embodiments provided in the following disclosure may be modified, reorganized, or combined to create other embodiments without departing from the scope of this disclosure. The feature between the various embodiments may be combined in any manner as long as the features do not conflict with each other or violate the scope of the disclosure.

For the sake of illustration, some drawings are described in conjunction with a three-dimensional Cartesian coordinate system. In the three-dimensional Cartesian coordinate system formed by directions X, Y, and Z, the direction X and the direction Y are perpendicular to each other and parallel to the planar surface of the flexible substrate, while the direction Z is parallel to the normal direction of the planar surface of the flexible substrate. In the three-dimensional Cartesian coordinate system formed by directions D1, D2, and D3, the direction D1 and the direction D2 are perpendicular to each other and parallel to the planar surface of the flexible substrate, while the direction D3 is parallel to the normal direction of the planar surface of the flexible substrate. The direction D1 may be parallel to the direction Y, or may be non-parallel to the direction Y and includes an angle therebetween.

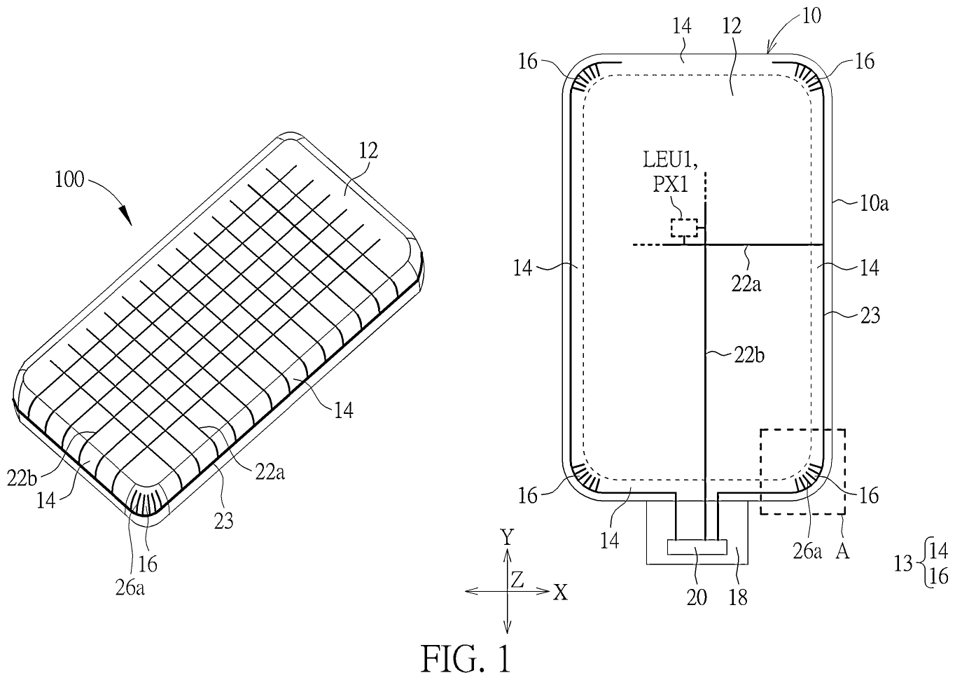

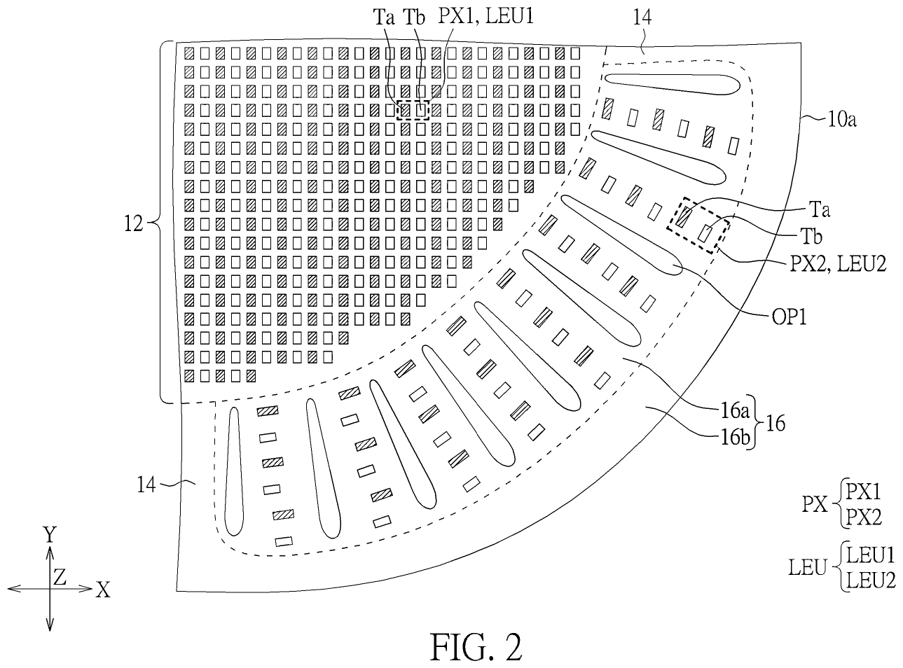

Please refer to FIG. 1 and FIG. 2. The left side of FIG. 1 is a schematic perspective view of the electronic device 100 according to an embodiment of this disclosure. The right side of FIG. 1 is a schematic plan view of the electronic device 100. FIG. 2 is a schematic plan view of area A of the electronic device 100 shown in FIG. 1. The electronic device 100 can be various types of displays or any electronic device equipped with a display screen. The electronic device 100 includes a flexible substrate 10. The front surface of the flexible substrate 10 (as illustrated on the right side of FIG. 1) includes a main region 12 (i.e., the first region) and a peripheral region 13 located between the main region 12 and the edge 10a of the flexible substrate 10. The edge 10a refers to the outer contour of the flexible substrate 10. The main region 12 constitutes the front surface of the electronic device 100, and includes a flat portion that is the part of the flexible substrate 10 that is not bent. The peripheral region 13 includes a side region 14 and a corner region 16, wherein the side region 14 constitutes the side portion of the electronic device 100, and the corner region 16 constitutes the corner portion of the electronic device 100 (i.e., the second region). The side region 14 and the corner region 16 are the parts of the flexible substrate 10 that are bent and include curved surfaces. In some embodiments, the corner region 16 may include an opening portion 16a and an arc portion 16b. The opening portion 16a includes multiple first openings OP1 to help the corner region 16 to be bent into the desired shape and angle easier. The first openings OP1 are arranged in a fan shape within the opening portion 16a. The arc portion 16b has an arc profile along the edge 10a. In some embodiments, one side of the flexible substrate 10 may include a bending region 18, on which a control chip 20 may be provided. The bending region 18 may be bent towards the back side of the flexible substrate 10 (the back of the drawing). The control chip 20 may include a driving chip or a sensing chip, but is not limited thereto. In some embodiments, another flexible substrate (not shown) may be bonded to the edge 10a as a control board for placing the control chip 20. In some embodiments, the control chip 20 may be directly placed on the peripheral region 13 of the flexible substrate 10.

A plurality of electronic units LEU and driving circuit units PX that are electrically connected to the electronic units LEU to control their operation are disposed on the flexible substrate 10. The types of electronic units LEU are selected based on the type and function of the electronic device 100. For example, when the electronic device 100 is a display device, the electronic units LEU may include chips, light-emitting diodes, variable capacitors, variable resistors, varactor diodes, any other suitable electronic components, or combinations thereof, but are not limited thereto. The arrangements of the electronic units LEU on the flexible substrate 10 may be adjusted according to display requirements. For example, as shown in FIG. 1 and FIG. 2, the electronic units LEU include a first electronic unit LEU1 disposed on the main region 12 and a first driving circuit unit PX1 that is electrically connected to the first electronic unit LEU1, as well as a second electronic unit LEU2 disposed on the opening portion 16a of the corner region 16 and a second driving circuit unit PX2 that is electrically connected to the second electronic unit LEU2. In some embodiments, electronic units LEU and driving circuit units PX may also be provided in the side region 14, but are not shown in the drawing for simplicity.

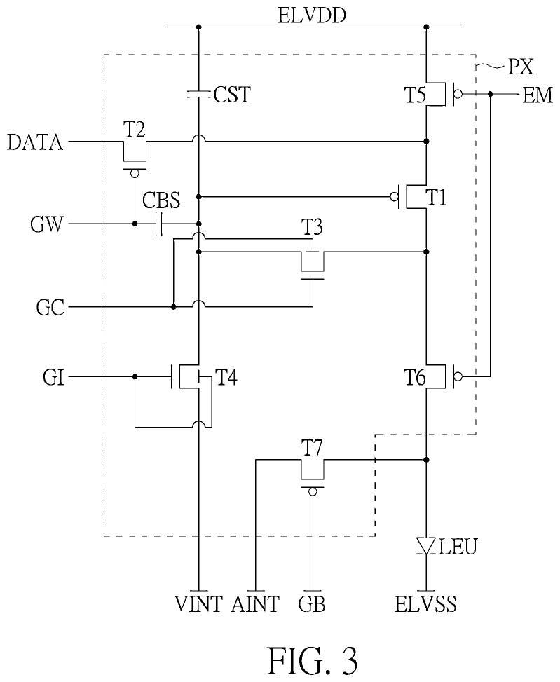

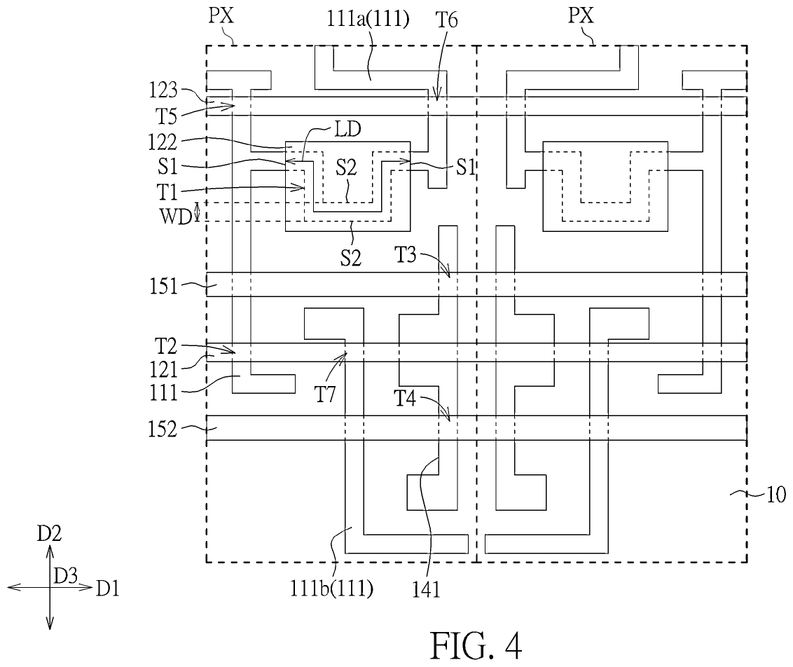

Each driving circuit unit PX is a complete circuit capable of driving the full operation of the connected electronic unit LEU. Each driving circuit unit PX includes multiple transistors and capacitors. To simplify the drawings, FIG. 2 only schematically depicts two of the transistors Ta and Tb of each driving circuit unit PX. Transistor Ta and transistor Tb may be any two of the transistors T1 to T7 of the driving circuit unit PX as shown in either FIG. 3 or FIG. 4. The sizes, shapes, and arrangements of the transistors shown in the drawings are merely illustrative and should be understood in conjunction with the descriptions in the description to understand the features of the disclosure. In some embodiments, the first driving circuit unit PX1 and the second driving circuit unit PX2 may include different types of transistors, for example, the first driving circuit unit PX1 may include thin film transistors (TFT), while the second driving circuit unit PX2 may be a micro driving circuit (micro IC) that includes other types of transistors.

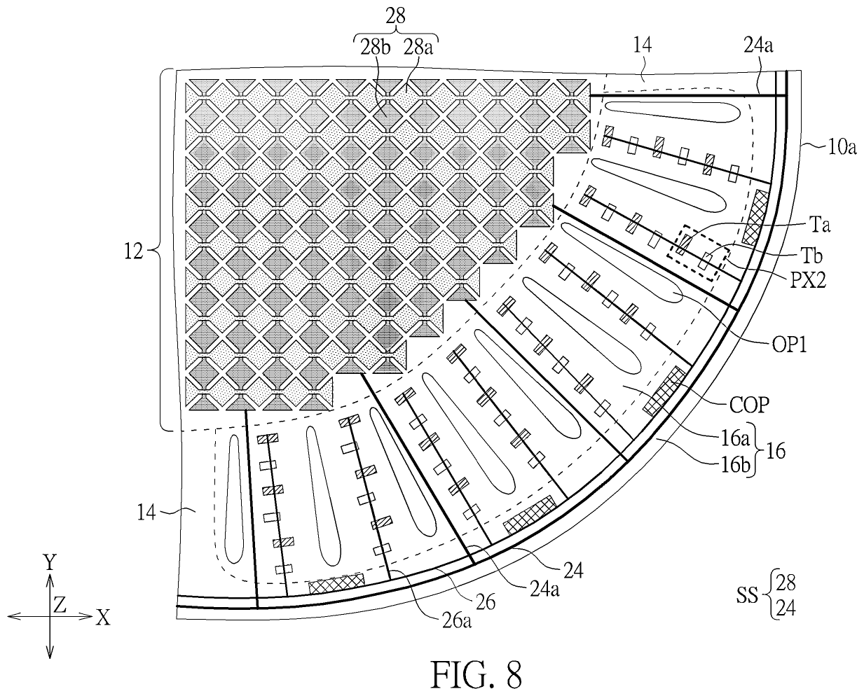

The flexible substrate 10 further includes circuit traces disposed thereon for electrically connecting the driving circuit unit PX and the control chip 20. The circuit traces may include data lines (DL), scan lines (SL), emission control lines (EM), power lines (PVDD), ground potential lines (PVSS), clock signal lines, etc., but are not limited thereto. Depending on the shape and position of different regions of the flexible substrate 10, the arrangement of the circuit traces may be adjusted to ensure smooth connections to each driving circuit unit PX. As shown in FIG. 1, the main region 12 may include circuit traces 22a and 22b that are arranged parallel along the X or Y direction and are electrically connected to the first driving circuit unit PX1. The corner region 16 may include conductive lines 26a arranged in a fan shape and electrically connected to the second driving circuit unit PX2. In some embodiments, the conductive lines 22a and 26a may be electrically connected to the control chip 20 through circuit traces on the peripheral region 13, such as the conductive lines 23 and 26 shown in FIG. 1 and FIG. 8.

Please refer to FIG. 3, which shows the equivalent circuit diagram of the driving circuit unit PX and the electronic unit LEU for an embodiment of this disclosure. The electronic unit LEU is, for example, a light-emitting diode, and the driving circuit unit PX can provide the driving current to the electronic unit LEU, causing the electronic unit LEU to emit light.

Each driving circuit unit PX includes multiple transistors and capacitors. As shown in FIG. 3, the driving circuit unit PX may include transistors T1 to T7, as well as storage capacitor CST and boost capacitor CBS. The electronic unit LEU that is connected to the driving circuit unit PX may include two terminals, namely a first terminal (e.g., an anode terminal) and a second terminal (e.g., a cathode terminal), wherein the first terminal is connected to the transistors T6 and T7, and the second terminal is connected to the ground voltage ELVSS. The electronic unit LEU can generate light with brightness corresponding to the drive current. The storage capacitor CST may include a first terminal and a second terminal, where the first terminal is connected to the transistor T1, and the second terminal is connected to the power supply voltage ELVDD. The storage capacitor CST can maintain the gate voltage level of the transistor T1 during the inactive period of the first gate signal GW. The boost capacitor CBS may include a first terminal and a second terminal, where the first terminal is connected to the second terminal of the transistor T3 and the gate terminal of the transistor T1, and the second terminal is connected to the first gate signal GW. When the first gate signal GW is stopped, the boost capacitor CBS can increase the gate voltage of the transistor T1 to compensate for the gate voltage drop.

The transistor T1 includes three terminals, namely a gate terminal, a first terminal (as a source terminal), and a second terminal (as a drain terminal). The gate terminal of the transistor T1 may be connected to the first terminal of the storage capacitor CST and the first terminal of the boost capacitor CBS. The first terminal of the transistor T1 is connected to the transistor T2 for receiving the data signal DATA. The second terminal of the transistor T1 is connected to the transistor T6. The transistor T1 can generate a drive current based on the voltage difference between the gate terminal and the first terminal. In some embodiments, the transistor T1 may also be referred to as a drive transistor. In some embodiments, the transistor T1 is an N-channel metal-oxide-semiconductor (NMOS) transistor.

The transistor T2 includes three terminals, namely a gate terminal, a first terminal (as a source terminal), and a second terminal (as a drain terminal). The gate terminal of the transistor T2 is connected to the first gate signal GW, which controls the on-state or off-state of the transistor T2. In some embodiments, the transistor T2 is a P-channel metal-oxide-semiconductor (PMOS) transistor, which is turned off when the first gate signal GW is at a positive voltage level, and is turned on when the first gate signal GW is at a negative voltage level. The first terminal of the transistor T2 is connected to the data signal DATA. The second terminal of the transistor T2 may provide the data signal DATA to the first terminal of the transistor T1 while the transistor T2 is at the on-state. In some embodiments, the transistor T2 may also be referred to as a switch transistor.

The transistor T3 includes four terminals, namely a top-gate terminal, a bottom-gate terminal, a first terminal (as a source terminal), and a second terminal (as a drain terminal). The top-gate terminal and the bottom-gate terminal of the transistor T3 is connected to the second gate signal GC. The first terminal of the transistor T3 is connected to the second terminal of the transistor T1. The second terminal of the transistor T3 can be connected to the gate terminal of the transistor T1. The on-state or off-state of the transistor T3 is controlled by the second gate signal GC. In some embodiments, the transistor T3 is an N-type channel metal-oxide-semiconductor (NMOS) transistor, which is turned on when the second gate signal GC is at a positive voltage level and is turned off when the second gate signal GC is at a negative voltage level. During the period when the transistor T3 is turned on by the second gate signal GC, the transistor T3 can be diode-connected to the transistor T1. The transistor T3 can compensate for the threshold voltage of the transistor T1. In some embodiments, the transistor T3 may also be referred to as a compensation transistor.

The transistor T4 includes four terminals, namely the top-gate terminal, the bottom-gate terminal, the first terminal (such as a source terminal), and the second terminal (such as a drain terminal). The top-gate terminal and the bottom-gate terminal of the transistor T4 are connected to the third gate signal GI. The first terminal of the transistor T4 is connected to the gate terminal of transistor T1. The second terminal of transistor T4 is connected to the gate initialization voltage VINT. The on-state or off-state of the transistor T4 is controlled by the third gate signal GI. In some embodiments, transistor T4 is an NMOS transistor, which is turned on when the third gate signal GI is at a positive voltage level and is turn off when the third gate signal GI is at a negative voltage level. During the period when the transistor T4 is turned on by the third gate signal GI, the gate initialization voltage VINT may be provided to the gate terminal of the transistor T1, thereby initializing the gate terminal of the transistor T1 to the gate initialization voltage VINT. In some embodiments, the transistor T4 may also be referred to as the gate initialization transistor.

The transistor T5 includes three terminals, namely a gate terminal, a first terminal (as a source terminal), and a second terminal (as a drain terminal). The gate terminal of the transistor T5 is connected to the light control signal EM. The first terminal of the transistor T5 is connected to the power supply voltage ELVDD. The second terminal of the transistor T5 is connected to transistor T1. When the transistor T5 is turned on by the light control signal EM, the power supply voltage ELVDD may be provided to the transistor T1.

The transistor T6 includes three terminals, namely a gate terminal, a first terminal (as a source terminal), and a second terminal (as a drain terminal). The gate terminal of the transistor T6 is connected to the light control signal EM. The first terminal of the transistor T6 is connected to the transistor T1. The second terminal of the transistor T6 is connected to the electronic unit LEU. When transistor T6 is turned on by the light control signal EM, the driving current may be provided to the electronic unit LEU.

The transistor T7 includes three terminals, namely a gate terminal, a first terminal (as a source terminal), and a second terminal (as a drain terminal). The gate terminal of the transistor T7 is connected to the fourth gate signal GB. The first terminal of the transistor T7 is connected to the electronic unit LEU. The second terminal of the transistor T7 is connected to the anode initialization voltage AINT. When the transistor T7 is turned on by the fourth gate signal GB, the anode initialization voltage AINT may be provided to the electronic unit LEU, thereby initializing the first terminal of the electronic unit LEU to the anode initialization voltage AINT. In some embodiments, the transistor T7 may also be referred to as the anode initialization transistor.

In some embodiments, the transistors T1, T2, T5, T6, and T7 are PMOS transistors, while the transistors T3 and T4 are NMOS transistors, wherein the active regions of the PMOS transistors may include P-type doped silicon-based semiconductor materials, and the active regions of the NMOS transistors may include oxide semiconductor materials. Additionally, the first gate signals GW, the light control signal EM, and the fourth gate signal GB used to turn on each of the transistors T2, T5, T6, and T7 can have negative voltage levels, while the second gate signal GC and the third gate signal GI used to turn on transistors T3 and T4 can have positive voltage levels. In this disclosure, the gate terminal, the top-gate terminal, and the bottom-gate terminal of the transistors may all be referred to as control terminals. The driving circuit unit PX shown in FIG. 3 and the circuit of the electronic unit LEU are merely examples and may be adjusted according to 1 application requirements.

Please refer to FIG. 4, which is a schematic plan view of the driving circuit unit PX (including the first driving circuit unit PX1 and the second driving circuit unit PX2) according to an embodiment of the present disclosure. To simplify the drawing, FIG. 4 only shows the semiconductors and the gate structures (or gate lines) of the transistors T1 to T7 that constitute the driving circuit unit PX, and other structures are omitted.

The channel region of the transistor is the part of the semiconductor that overlaps with the gate structure (or gate line). From the plane view, the channel region may include two edges S1 that are aligned with the edges of the gate structure (or the gate line), and another two edges S2 that are covered by the gate structure (or the gate line). As shown in FIG. 4, the layouts of arrangements of the adjacent driving circuit units PX may be mirror symmetrical. Each driving circuit unit PX includes a first semiconductor 111 and a second semiconductor 141 arranged on a flexible substrate 10, wherein the transistors T1, T2, T5, and T6 are formed by different parts of the same first semiconductor 111a, the transistor T7 is formed by another first semiconductor 111b, and the transistors T3 and T4 are formed by different parts of the same second semiconductor 141. The island-like gate structure 122 overlaps part of the first semiconductor 111 to form the transistor T1. The gate line 123 extends along the direction D1 and crosses two different parts of the first semiconductor 111a to form the transistor T5 and the transistor T6. The gate line 121 extends along the direction D1 and crosses another part of the first semiconductor 111a and a part of the first semiconductor 111b to form the transistor T2 and the transistor T7. The gate line 151 extends along the direction D1 and crosses a part of the second semiconductor 141 to form the transistor T3. The gate line 152 extends along the direction D1 and crosses another part of the second semiconductor 141 to form the transistor T4. It should be understood that the layout of arrangement of the driving circuit unit PX shown in FIG. 4 is only an example. The relative position between the transistors T1 to T7 may be adjusted according to the application requirements. In some embodiments, the first semiconductor 111a and the first semiconductor 111b may be connected.

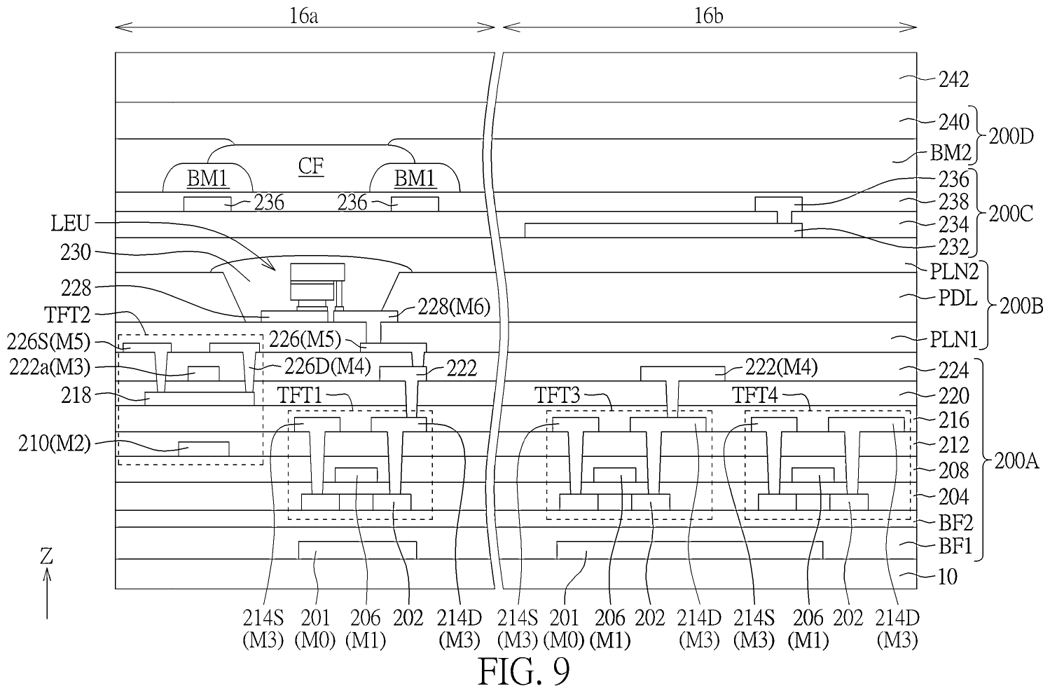

The first semiconductor 111, the second semiconductor 141, the gate structure 122, the gate line 123, the gate line 121, the gate line 151 and the gate line 152 may be arranged in a circuit layer disposed on the flexible substrate 10 (such as the circuit layer 200A as shown in FIG. 9). The first semiconductor 111 and the second semiconductor 141 may respectively include a single layer structure or a multilayer structure. In some embodiments, the first semiconductor 111 and the second semiconductor 141 may respectively include, but are not limited to, a silicon-based semiconductor material, an oxide semiconductor material, or a combination of the above materials, wherein the materials of the first semiconductor 111 and the second semiconductor 141 may be the same or different. In some embodiments, the materials of the first semiconductor 111a and the first semiconductor 111b include, silicon, such as amorphous silicon (a-silicon), low-temperature polycrystalline silicon (LTPS), or single crystalline silicon (c-Si), but are not limited thereto. In some embodiments, the material of the second semiconductor 141 includes oxide semiconductor material, such as Indium Gallium Zinc Oxide (IGZO), Indium Gallium Tin Oxide (Indium Gallium Tin Oxide, IGTO) or Indium Gallium Zinc Tin Oxide (IGTZO), but is not limited thereto. In some embodiments, the semiconductors of the transistors T1, T2, T3, T5, T6 and T7 include silicon, and the semiconductors of transistors T3, T4 include oxides. The gate structure 122, the gate line 123, the gate line 121, the gate line 151 and the gate line 152 may have a single layer or multiple layers of conductive materials, respectively, wherein suitable conductive materials may include at least one of aluminum (Al), copper (Cu), silver (Ag), chromium (Cr), titanium (Ti), molybdenum (Mo), nickel (Ni), Monium (Mc) and other metallic materials, composite layers of the said metal materials or alloys of the said metal materials, but is not limited thereto. According to some embodiments of the present disclosure, the gate structure 122, the gate line 123, the gate line 121, the gate line 151 and the gate line 152 respectively have a multilayer structure including, for example, molybdenum (Mo)/aluminum (Al), titanium (Ti)/aluminum (Al), molybdenum (Mo)/copper (Cu), titanium (Ti)/Copper (Cu), molybdenum (Mo)/aluminum (Al), molybdenum (Mo), titanium (Ti)/aluminum (Al)/titanium (Ti), molybdenum (Mo)/copper (Cu), molybdenum (Mo), titanium (Ti)/copper (Cu), or titanium (Ti), but is not limited thereto.

The driving circuit unit PX disposed on different regions of the flexible substrate 10 may have different designs of layout of arrangement to accommodate the stresses in different portions, thereby obtaining an improved quality. For example, the layout of arrangement of the transistors T1 to T7 of the second driving circuit unit PX2 may be adjusted according to the stress distribution in the corner region 16. The adjustment to the layout of arrangement may include, but not limited to, adjusting the arrangement, adjusting the areas, and/or adjusting the distance between the second driving circuit unit PX2, by which an optimized layout of arrangement of the driving circuit unit PX that the transistors T1 to T7 have smaller channel stress may be obtained. In this way, the risk of abnormal performance or structural defect of the transistors T1 to T7 may be reduced, and the product reliability may be improved.

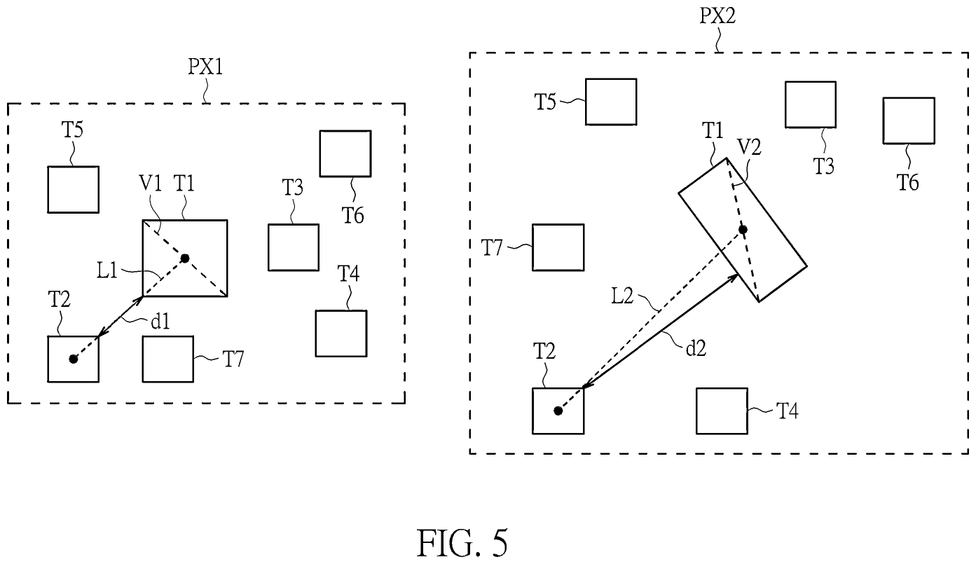

Please refer to FIG. 5. The left side of FIG. 5 shows a schematic layout of the transistors T1 to T7 of the first driving circuit unit PX1 according to an embodiment of this disclosure, and the right side of FIG. 5 shows a schematic layout of the transistors T1 to T7 of the second driving circuit unit PX2 according to an embodiment of this disclosure. Each square block represents the channel region of the transistors T1 to T7. It should be noted that the transistors T1 to T7 of the first driving circuit unit PX1 and the second driving circuit unit PX2 shown in FIG. 5 are not limited to sequentially corresponding to the transistors T1 to T7 in FIG. 3 or FIG. 4. For example, the transistor T1 in FIG. 5 may correspond to the transistor T1 in FIG. 4, and the transistor T2 in FIG. 5 may correspond to the transistor T3 or the transistor T4 in FIG. 4. The correspondence between the transistors shown in FIG. 5 and FIG. 4 are not limited to the above.

As shown in FIG. 5, the layout arrangement of the transistors T1 to T7 of the first driving circuit unit PX1 is different from the layout of arrangement of the transistors T1 to T7 of the second driving circuit unit PX2. The differences may include the distance between two specific transistors (two transistors with specific functions) among T1 to T7, the extension direction of two specific transistors among T1 to T7, the channel length of one specific transistor (one transistor with a specific function) among T1 to T7, the channel width of one specific transistor among T1 to T7, the aspect ratio of the channel region of one specific transistor among T1 to T7, the area of the channel region of one specific transistor among T1 to T7, the direction of the channel region of one specific transistor among T1 to T7, the direction of the virtual diagonal of the channel region of one specific transistor among T1 to T7, or a combination of the aforementioned differences, but is not limited thereto.

In this disclosure, the channel region of the transistor refers to the part of the semiconductor overlaps with the gate structure (or gate line). The distance between two specific transistors is defined as the shortest distance (minimum distance) measured in the plane between the channel regions of those two transistors. The extension direction of the two specific transistors is defined as the direction of the line connecting the geometric centers of the minimum rectangles that enclose the channel regions of those two transistors (the rectangular pattern as shown in FIG. 5). Taking transistor T1 in FIG. 4 for example, the length LD of the channel region is defined as the length measured from one edge S1 to the other edge S1, while the width WD of the channel region is defined as the distance between the two edges S2. The width-to-length ratio (W/L ratio) of the channel region is defined as the ratio of width WD to length LD. The area of the channel region is defined as the overlapping area of the semiconductor and the gate structure (gate line), and the direction of the channel region is defined as the direction of the shortest distance measured between the two edges S1 in the plane. The virtual diagonal of the channel region of the transistor is defined as the diagonal of the minimum rectangle (see the rectangular pattern as shown in FIG. 5) that encloses the channel region of the transistor. The virtual diagonal may be the diagonal from the upper left corner to the lower right corner or from the upper right corner to the lower left corner.

In some embodiments, as shown in FIG. 5, the first driving circuit unit PX1 includes a first distance d1 and an extension direction L1 between the transistors T1 and the transistor T2. The second driving circuit unit PX2 includes a second distance d2 and an extension direction L2 between the transistors T1 and the transistor T2, wherein the first distance d1 is not equal to the second distance d2, and the extension direction L1 is not parallel to the extending direction L2. In some embodiments, the first distance d1 is smaller than the second distance d2, meaning that the arrangement of transistors in the second driving circuit unit PX2 is more dispersed compared to the arrangement of transistors in the first driving circuit unit PX1, and may result in a lower pattern density per unit area. This helps to alleviate stress between the transistors in the corner region 16, reducing the risk of performance anomalies or structural damage, thereby enhancing product reliability. In some embodiments, the first distance d1 and the second distance d2 satisfy the relationship 1>d2/d1>0.8.

In some embodiments, the channel region of the transistor T1 of the first driving circuit unit PX1 has a first area, while the transistor T1 of the second driving circuit unit PX2 has a second area, and the first area is different from the second area. In some embodiments, the first area is larger than the second area, meaning that the transistor of the second driving circuit unit PX2 has a reduced channel area compared to the transistor of the first driving circuit unit PX1. This may reduce the probability of the transistor of the second driving circuit unit PX2 being bent when the corner region 16 of the flexible substrate 10 is bent, thereby reducing the risk of structural damage and improving product reliability. In some embodiments, the first area is A1, the second area is A2, and the relationship 1>A2/A1>0.5 is satisfied.

In some embodiments, the channel region of the transistor T1 of the first driving circuit unit PX1 has a first width-to-length ratio, while the channel region of the transistor T1 of the second driving circuit unit PX2 has a second width-to-length ratio, and the first width-to-length ratio is different from the second width-to-length ratio. In some embodiments, the first width-to-length ratio is smaller than the second width-to-length ratio, meaning that the transistor of the second driving circuit unit PX2 has an increased width-to-length ratio compared to the transistor of the first driving circuit unit PX1, thereby having an increased current output limit. As a result, when the corner region 16 is subjected to stress, the second driving circuit unit PX2 may maintain the required current output performance, thereby enhancing product reliability. In some embodiments, the channel region of the transistor T1 of the first driving circuit unit PX1 has a width Wa and a length La with a width-to-length ratio Wa/La, while the channel region of the transistor T1 of the second driving circuit unit PX2 has a width Wb and a length Lb with a width-to-length ratio Wb/Lb, and the relationship 1>(Wb/Lb)/(Wa/La)>0.7 is satisfied.

In some embodiments, the channel region of the transistor T1 of the first driving circuit unit PX1 has a first length, while the channel region of the transistor T1 of the second driving circuit unit PX2 has a second length, and the first length being different from the second length. In some embodiments, the first length is larger than the second length, meaning that the transistor in the second driving circuit unit PX2 has a reduced channel region length compared to the transistor in the first driving circuit unit PX1, thereby achieving an increased current output limit. As a result, when the corner region 16 is subjected to stress, the second driving circuit unit PX2 may maintain the required current output performance and enhancing product reliability. In some embodiments, the channel region of the transistor T1 in the first driving circuit unit PX1 has a length La, while the channel region of the transistor T1 in the second driving circuit unit PX2 has a length Lb, and the relationship 1>Lb/La>0.7 is satisfied.

In some embodiments, the channel region of the transistor T1 of the first driving circuit unit PX1 has a first virtual diagonal line VI extending from the upper left corner to the lower right corner, while the channel region of the transistor T1 of the second driving circuit unit PX2 has a second virtual diagonal line V2 extending from the upper left corner to the lower right corner. The first virtual diagonal line VI is not parallel to the second virtual diagonal line V2, meaning that the direction of the channel region of the transistor T1 of the second driving circuit unit PX2 is rotated at an angle relative to the direction of the channel region of the transistor of the first driving circuit unit PX1 to minimize the stress of the second driving circuit unit PX2 in the corner region 16, thereby reducing the risk of structural damage caused by stress, and the product reliability is enhanced.

The features described above regarding the first driving circuit unit PX1 and the second driving circuit unit PX2, specifically for transistors T1 and T2, may also apply to other specific two of the transistors among T1 to T7. For example, the features can apply to transistors T1 and T3, T1 and T4, T1 and T5, T1 and T6, T1 and T7, T2 and T3, T2 and T4, T2 and T5, T2 and T6, T2 and T7, T3 and T4, T3 and T5, T3 and T6, T3 and T7, T4 and T5, T4 and T6, T4 and T7, T5 and T6, and T6 and T7. In some embodiments, the specific two of transistors are respectively located at the farthest diagonal position within the driving circuit unit, such as the transistors T4 and T5 shown in FIG. 4.

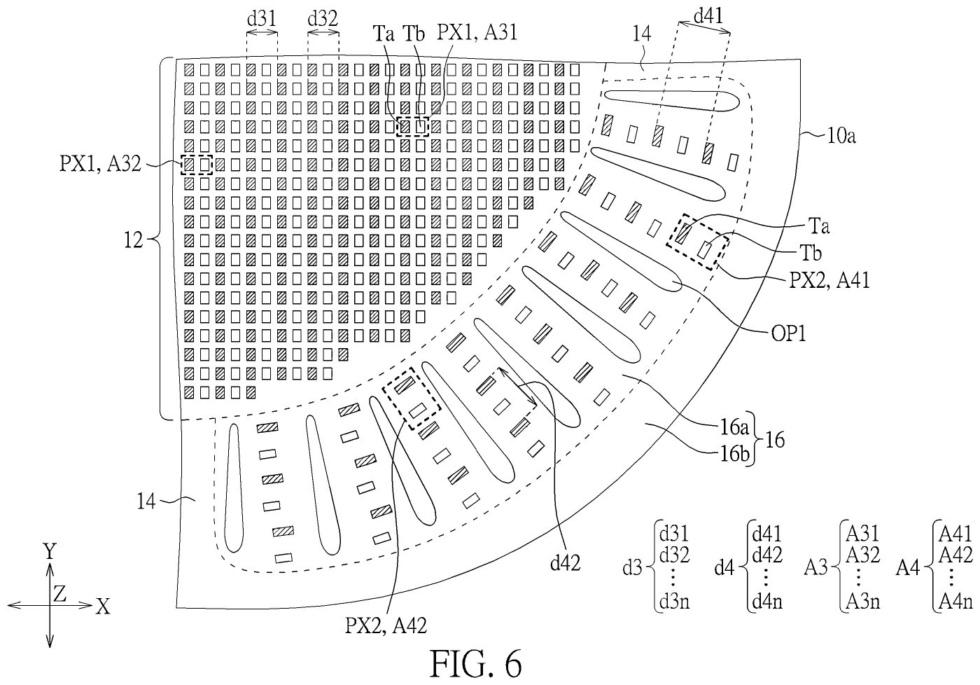

Please refer to FIG. 6, which is a schematic plan view of a part of an electronic device, such as the region A of the electronic device 100 shown in FIG. 1 according to an embodiment of this disclosure. In some embodiments, due to the differences in the areas and arrangement of the transistors, the differences between the first driving circuit unit PX1 and the second driving circuit unit PX2 may also include the area of the driving circuit units, the distance between adjacent driving circuit units, or a combination thereof, but is not limited thereto. In this document, the area of the driving circuit unit is defined as the area of the smallest rectangle that encompasses the channel regions of all transistors (for example, the transistors T1 to T7) of the driving circuit unit. The distance between two adjacent driving circuit units is defined as the distance such as the minimum distance measured on the plane between the channel regions of the same transistor (for example, the transistor Ta, wherein the transistor Ta may be any one of the transistors T1 to T7) of the two adjacent driving circuit units.

As shown in FIG. 6, any two adjacent first driving circuit units PX1 in the main region 12 may include a distance d3, such as the distances d31, d32 . . . d3n. Any two adjacent second driving circuit units PX2 in the corner region 16 may include a distance d4, such as the distances d41, d42 . . . d4n. The distances d3 and d4 may not be different. In some embodiments, the distance d4 is larger than the distance d3. In some embodiments, the first driving circuit units PX1 in the main region 12 are arranged at approximately equal intervals along the X direction and the Y direction, and the distances d3 measured between different couples of adjacent first driving circuit units PX1 (such as the distances d31, d32 . . . d3n) are approximately equal and have a relatively small standard deviation SDV1. The second driving circuit units PX2 in the corner region 16 can be adaptively adjusted based on the shape, curvature, and/or stress distribution of the corner region 16, meaning that the distances d4 measured by different couples of adjacent second driving circuit units PX2 (such as the distances d41, d42 . . . d4n) may be different, and have a relatively large standard deviation SDV2. In some embodiments, the standard deviation SDV2 is greater than the standard deviation SDV1.

Please continue to refer to FIG. 6. Any first driving circuit unit PX1 in the main region 12 has an area A3, such as area A31, area A32. . . . A3n. Any second driving circuit unit PX2 in the corner area 16 has an area A4, such as area A41, area A42. . . . A4n. In some embodiments, the area A4 is larger than the area A3. Furthermore, the areas A3 of different first driving circuit units PX1 are approximately equal and have a relatively small standard deviation SDV3. The areas A4 of different second driving circuit units PX2 may not be different and have a relatively large standard deviation SDV4. In some embodiments, the standard deviation SDV4 is larger than the standard deviation SDV3.

The second driving circuit units PX2 located in corner region 16 may have different distances d4 and areas A4, providing a larger layout flexibility to accommodate the stresses in the corner region 16. In this way, the transistors (particularly the largest transistor T1) may be arranged wherever has a relatively lower stress, thereby reducing the risk of structural damage caused by stress and enhancing product reliability. Additionally, by varying the spacing and areas of the second driving circuit unit PX2 in corner region 16, it is possible to balance the stress distribution in the corner region 16, as well as provides visual compensation for different viewing angles form the corner region 16.

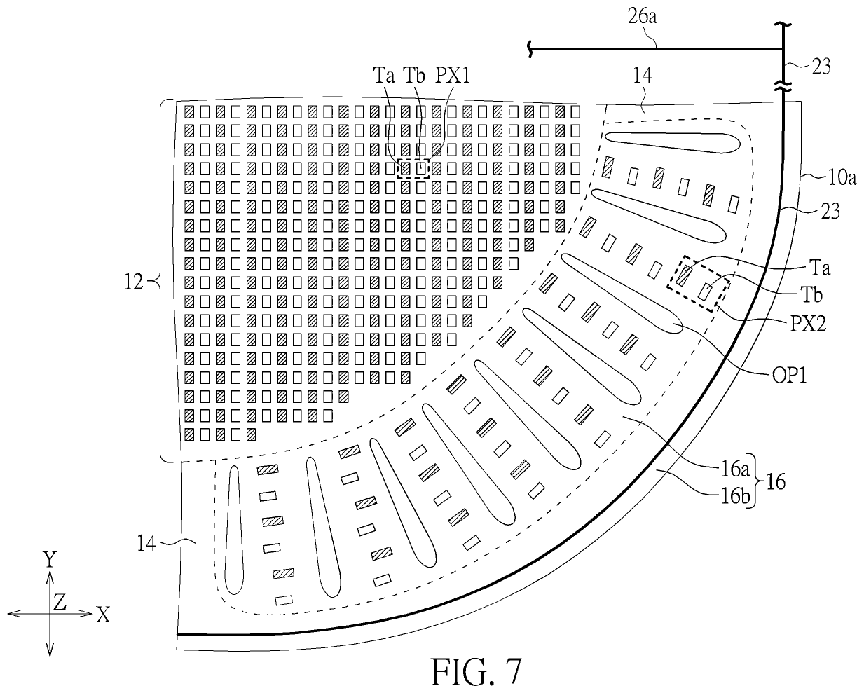

Please refer to FIG. 7 and FIG. 8, and also refer to FIG. 1. FIG. 1 and FIG. 8 are schematic plan views of a part of an electronic device such as the region A of the electronic device 100 shown in FIG. 1 according to an embodiment of this disclosure. In some embodiments, the arc portion 16b of the corner region 16 can be used as a circuit routing region. For example, as shown in FIG. 7 and FIG. 1, the conductive lines 23 may extend through the arc portion 16b to the side region 14 and connect to the conductive lines 22a to provide a signal to the first driving circuit units PX1 in the main region 12. As shown in FIG. 8 and FIG. 1, the conductive lines 26 may be placed on the arc portion 16b and electrically connected to the conductive lines 26a to provide a signal to the second driving circuit units PX2 in the opening portion 16a of the arc portion 16. The conductive lines 23 and 26 may respectively be data lines, scan lines, light control lines, power lines, ground potential lines, clock signal lines, etc., but are not limited thereto.

In some embodiments, the electronic device 100 further includes a sensing circuit SS to provide sensing functions, such as touch sensing, biometric sensing, distance sensing, and electromagnetic wave sensing, but is not limited thereto. As shown in FIG. 8, the sensing circuit SS may include sensing electrodes 28 and conductive lines 24. The sensing electrodes 28 are arranged on the planar portion of the main region 12 and may include first axial electrodes 28a and second axial electrodes 28b for sensing signals. The conductive lines 24 are arranged on the main region 12 and the peripheral region 13 (shown in FIG. 1), and are electrically connected to the sensing electrodes 28 to transmit the signals from the sensing electrodes 28 to, for example, a sensing chip located in the bending region 18. As shown in FIG. 8, some conductive lines 24 may be arranged on the arc portion 16b of the corner region 16, and then electrically connected to the sensing electrodes 28 at the portion of the main region 12 adjacent to the corner region 16 through the interconnecting lines 24a that extend through the corner region 16.

The conductive lines 23, 26, and 24 can be formed in different layers of the circuit layer (such as the circuit layer 200A shown in FIG. 9). In some embodiments, as shown in FIG. 8, circuit components COP such as decoders, chip-on-wafer packages, or gate driving circuits which may provide gate signals (such as the first gate signal GW, the second gate signal GC, the third gate signal GI, and the fourth gate signal GB) to the second driving circuit unit may be disposed on the arc portion 16b, but are not limited thereto.

Please refer to FIG. 9, which is a schematic cross-sectional view of an electronic device according to an embodiment of this disclosure. The electronic device may be, for example, the electronic device 100 shown in FIG. 1. The left side of FIG. 9 shows a schematic cross-sectional structure of the opening portion 16a of the corner region 16, while the right side of FIG. 9 shows a schematic cross-sectional structure of the arc portion 16b of the corner region 16. The main region 12 of the electronic device 100 may have a cross-sectional structure as shown on the left side of FIG. 9. As shown in FIG. 9, the electronic device 100 includes a flexible substrate 10. A circuit layer 200A, a device layer 200B, an optical layer 200D and a protective layer 242 are arranged from bottom to top on the flexible substrate 10. In some embodiments, a touch layer 200C may be provided between the device layer 200B and the optical layer 200D. The flexible substrate 10 may comprise any suitable flexible or bendable material, such as polyimide (PI), polycarbonate (PC), polyethylene naphthalate (PEN), polyethylene terephthalate (PET), or other polymer materials or combinations thereof, but is not limited thereto.

The circuit layer 200A includes a multi-layer structure, which comprises driving circuit units and conductive lines for controlling the light emission of the electronic units LEU, such as transistors, capacitors, data lines, scan lines, light control lines, power lines, ground potential lines, clock signal lines, fan-out circuits, and/or pixel electrodes, but are not limited thereto. In some embodiments, the circuit layer 200A may sequentially, from bottom to top, include a first buffer layer BF1, a second buffer layer BF2, a first semiconductor 202, a dielectric layer 204, a first conductive layer M1, a dielectric layer 208, a second conductive layer M2, a dielectric layer 212, a third conductive layer M3, a dielectric layer 216, a second semiconductor 218, a dielectric layer 220, a fourth conductive layer M4, a dielectric layer 224, and a fifth conductive layer M5 from bottom to top. The first buffer layer BF1, the second buffer layer BF2, the dielectric layers 204, 208, 212, 216, 220, and 224 may respectively include a single-layer or a multi-layer dielectric materials such as silicon nitride (SiNx), silicon oxide (SiOx), silicon oxynitride (SiON), aluminum oxide (Al₂O₃), titanium oxide (TiO₂), tantalum oxide (Ta₂O₅), hafnium oxide (HfO₂), or zirconium oxide (ZrO₂), or a combinations thereof, but are not limited thereto. The first conductive layer M1, the second conductive layer M2, the third conductive layer M3, the fourth conductive layer M4, and the fifth conductive layer M5 may respectively include a single-layer or multi-layers of conductive materials, wherein the suitable conductive materials may include at least one selected from a group comprising aluminum (Al), copper (Cu), silver (Ag), chromium (Cr), titanium (Ti), molybdenum (Mo), nickel (Ni), any other metal materials, composite layers of the above metal materials, or alloys of the above metal materials, but are not limited thereto. The material of the first semiconductor 202 includes silicon, such as amorphous silicon, low-temperature polycrystalline silicon, or single-crystal silicon, but is not limited thereto. The material of the second semiconductor 218 includes oxides, such as indium gallium zinc oxide, indium gallium tin oxide, or indium gallium zinc oxide, but is not limited thereto.

The circuit layer 200A of the opening portion 16a includes transistors TFT1 and TFT2. The circuit layer 200A of the arc portion 16b includes transistors TFT3 and TFT4. The transistors TFT1, TFT3, and TFT4 are silicon-based thin-film transistors that the active regions thereof are made of the first semiconductor 202. The transistor TFT2 is an oxide semiconductor thin-film transistor that the active region thereof is made of the second semiconductor 218. The transistors TFT1, TFT3, and TFT4 are, for example, top-gate type transistors, wherein the gates 206 are made of the first conductive layer M1. The sources 214S and drains 214D are made of the third conductive layer M3. The transistor TFT2 is, for example, a double-gate type transistor, wherein the bottom-gate 210 is made of the second conductive layer M2, the top-gate 222a is made of the third conductive layer M3, and the source 226S and the drain 226D are made of the fourth conductive layer M4. The transistors T1, T2, T5, T6, and T7 illustrated in FIG. 3 and FIG. 4 may have the cross-sectional structure as shown for the transistor TFT1, and the transistors T3 and T4 may have the cross-sectional structure as shown for the transistor TFT2.

In some embodiments, the dielectric layer (such as the first buffer layer BF1) between the first semiconductor 202 and the flexible substrate 10 may include a bottom conductive layer M0. The conductive lines 23, 24, 24a, 26, and 26a shown in the FIG. 7 and FIG. 8 may be formed in any one of the first conductive layer M1, the second conductive layer M2, the third conductive layer M3, the fourth conductive layer M4, the fifth conductive layer M5, and the bottom conductive layer M0, according to design requirements. For example, the conductive lines 23, 24, 24a, 26, or 26a may be formed as the conductive lines 201 that are made of the bottom conductive layer M0, or the conductive lines 222 that is made of the fourth conductive layer M4.

The device layer 200B is formed on the circuit layer 200A and has a multi-layer structure. The device layer 200B, from bottom to top, may include a planarization layer PLN1, a sixth conductive layer M6, a pixel-define layer PDL, a encapsulate layer 230, and a planarization layer PLN2. The materials of the planarization layers PLN1, PLN2, the encapsulate layer 230, and the pixel-define layer PDL may include organic dielectric materials such as acrylic resin, siloxane resin, epoxy resin, or other suitable dielectric materials, but are not limited thereto. The material of the sixth conductive layer M6 may refer to the materials applicable to the conductive layers mentioned earlier, and will not be repeated herein for the sale of brevity. The pixel-define layer PDL includes openings that respectively expose the connection pads 228 which are made of the sixth conductive layer M6. The electronic units LEU are respectively placed in the openings of the pixel-define layer PDL, having the anode and cathode electrically connected to the connection pads 228, and are electrically connected to the driving circuit units in the underlying circuit layer 200A through conductive lines (such as the conductive lines 226). The encapsulate layer 230 fills the openings of the pixel-define layer PDL and covers the electronic units LEU.

The optical layer 200D is formed on the device layer 200B and has a multilayer structure. The optical layer 200D may include, from bottom to top, a first light-blocking layer BM1, a filter layer CF, a second light-blocking layer BM2, and an optical cover layer 240. The first light-blocking layer BM1 and the second light-blocking layer BM2 may include black polymer materials or resins, which are patterned to define openings that allow light generated by the electronic units LEU to pass through. The filter layer CF fills the openings defined by the first light-blocking layer BM1 and the second light-blocking layer BM2. The filter layer CF may allow lights of specific wavelengths to pass through, thereby achieving a color display effect. The materials of the filter layer CF may include red photoresist, blue photoresist, or green photoresist, but are not limited thereto. The first light-blocking layer BM1 and the second light-blocking layer BM2 between different colored filter layers CF may reduce mixing of lights of different colors. The optical cover layer 240 may include optical clear adhesive (OCA), optical clear resin (OCR), or other suitable dielectric materials, but is not limited thereto.

The protective layer 242 is formed on the optical layer 200D to protect the underlying circuit layer 200A, device layer 200B, and optical layer 200D. In some embodiments, the protective layer 242 may also provide additional optical compensation. The material of the protective layer 242 may include inorganic material, organic material, or a combination thereof. The inorganic material may include glass or other suitable materials, and the organic material may include polyethylene terephthalate (PET), acrylic polymer such as polymethyl methacrylate (PMMA), polyimide (PI), polycarbonate (PC), polysiloxane, and other polymer materials having high light transmittance, or a combination thereof, but is not limited thereto.

The touch layer 200C is set between the optical layer 200D and the device layer 200B. The touch layer 200C has a multi-layer structure that may include, from bottom to top, a conductive layer 232, a dielectric layer 234, a conductive layer 236, and a dielectric layer 238. The conductive layers 232 and 236 may include transparent conductive materials, such as indium tin oxide (ITO), indium gallium zinc oxide (IGZO), or aluminum zinc oxide (AZO), but are not limited thereto. The materials of the dielectric layers 234 and 238 may refer to the materials suitable for the other dielectric layers mentioned earlier, and will not be repeated herein for the sake of brevity. The conductive layers 232 and 236 may be patterned into conductive lines or touch electrodes. For example, the first axial electrodes 28a or the second axial electrodes 28b of the touch electrode 28 shown in FIG. 8 may be made of the conductive layers 232 and 236, respectively.

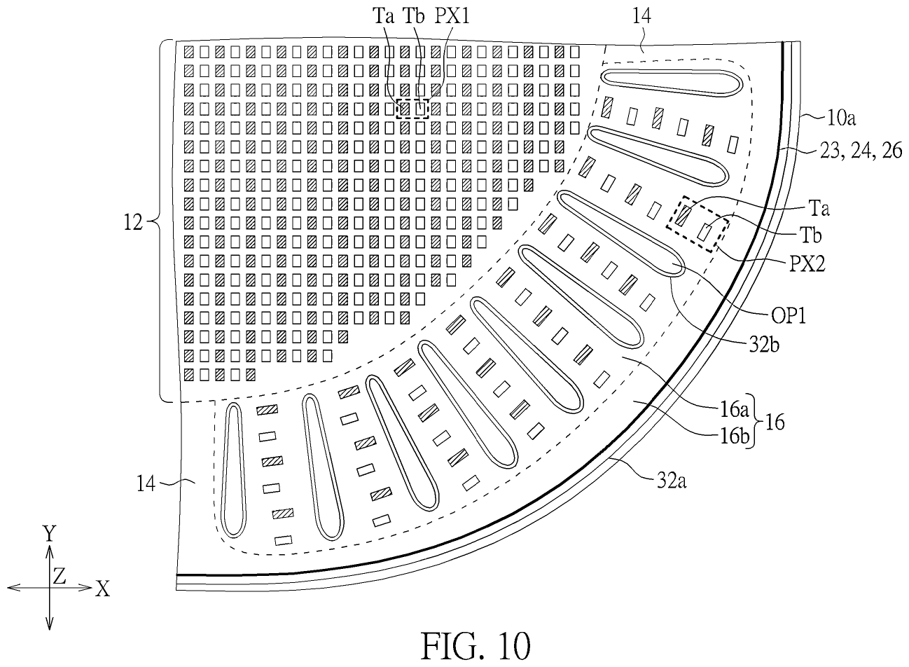

Please refer to FIG. 10, which is a schematic plan view of a part of an electronic device, such as the region A of the electronic device 100 shown in FIG. 1, according to an embodiment of this disclosure. The flexible substrate 10 may have crack-stop structures (such as grooves) to prevent cracks extending and causing serious structural damage when cutting of the flexible substrate 10. For example, a crack-stop structure 32a may be formed along the edge 10a (a cutting edge) of the flexible substrate 10. A crack-stop structure 32b may be formed around each of the first openings OP1. The conductive lines (such as the conductive lines 23, 24, and 26 as shown in FIG. 7 and FIG. 8) are arranged inside the portion of the flexible substrate 10 defined by the crack-stop structure 32a.

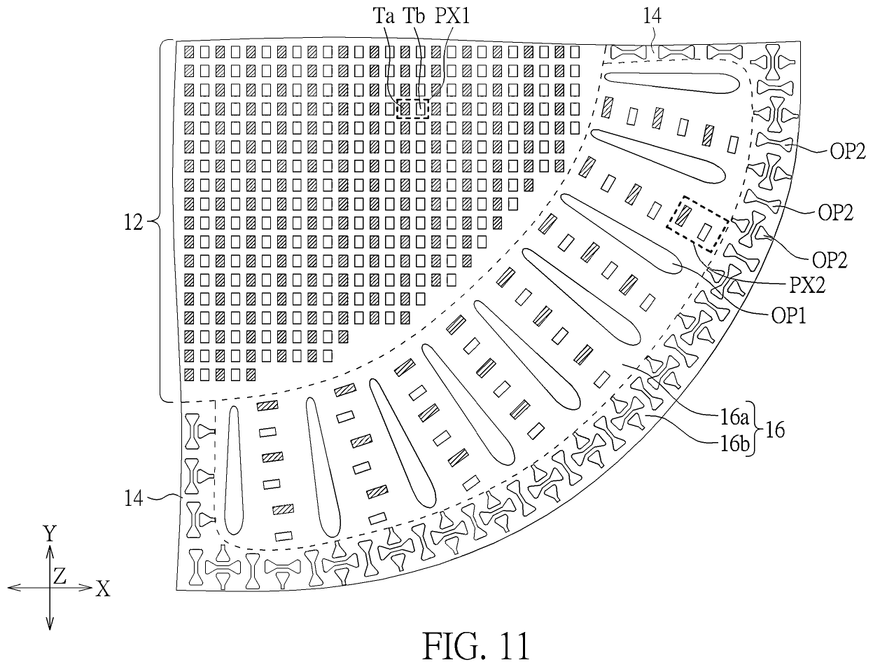

Please refer to FIG. 11, which is a schematic plan view of a part of an electronic device, such as the region A of the electronic device 100 shown in FIG. 1, according to an embodiment of this disclosure. The flexible substrate 10 may include openings other than the first opening OP1 formed in some portions of the peripheral region 13 to increase the flexibility or stretchability of portions of the peripheral region 13. For example, as shown in FIG. 11, a plurality of second openings OP2 are formed in the arc portion 16b of the corner region 16 to improve the flexibility or stretchability of the arc portion 16b. The first opening OP1 and the second openings OP2 may have different shapes. The areas of the first openings OP1 are larger than that the areas of the second opening OP2.

In summary, the electronic device provided by the present disclosure has driving circuit units in the corner region designed in a manner to accommodate the stresses in different portions of the corner region, thereby reducing the adverse effects of stress on the performance or structure integrity of transistors of the circuit units, and the product reliability may be improved. Furthermore, the electronic device may achieve a higher substrate area utilization rate by routing some conductive lines through the corner region to other regions of the substrate.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a flexible substrate with a first region and a second region between the first region and an edge of the flexible substrate;
a first electronic unit disposed on the first region of the flexible substrate;
a first driving circuit unit electrically connected to the first electronic unit, disposed on the first region of the flexible substrate and comprising a plurality of first transistors;
a second electronic unit disposed on the second region of the flexible substrate; and
a second driving circuit unit electrically connected to the second electronic unit, disposed on the second region of the flexible substrate and comprising a plurality of second transistors,
wherein a first arrangement of the plurality of first transistors is different from a second arrangement of the plurality of the second transistors.

2. The electronic device according to claim 1, wherein a terminal of one of the plurality of the first transistors is electrically connected to a control terminal of another one of the plurality of the first transistors, a terminal of one of the plurality of the second transistors is electrically connected to a control terminal of another one of the plurality of the second transistors, a first distance is between the one of the plurality of the first transistors and the another one of the plurality of the first transistors, a second distance is between the one of the plurality of the second transistors and the another one of the plurality of the second transistors, and the first arrangement is different from the second arrangement in that the first distance is different from the second distance.

3. The electronic device according to claim 2, wherein the first distance is smaller than the second distance.

4. The electronic device according to claim 2, wherein an extension direction from the one of the plurality of the first transistors to the another one of the plurality of the first transistors is not parallel to an extension direction from the one of the plurality of the second transistors to the another one of the plurality of the second transistors.

5. The electronic device according to claim 2, wherein the one of the plurality of the first transistors comprises a first semiconductor, the another one of the plurality of the first transistors comprises a second semiconductor, wherein the first semiconductor and the second semiconductor are made of different materials.

6. The electronic device according to claim 5, wherein the first semiconductor of the one of the plurality of the first transistors comprises oxide, the second semiconductor of the another one of the plurality of the first transistors comprises silicon.

7. The electronic device according to claim 2, wherein the one of the plurality of the first transistors and the another one of the plurality of the first transistors are respectively disposed at a diagonal of the first driving circuit unit, and the one of the plurality of the second transistors and the another one of the plurality of the second transistors are respectively disposed at a diagonal of the second driving circuit unit.

8. The electronic device according to claim 1, wherein a channel region of one of the plurality of the first transistors has a first width-to-length ratio, a channel region of one of the plurality of the second transistors has a second width-to-length ratio, and the first arrangement is different from the second arrangement in that the first width-to-length ratio and the second width-to-length ratio are different.

9. The electronic device according to claim 8, wherein the first width-to-length ratio is smaller than the second width-to-length ratio.

10. The electronic device according to claim 1, wherein a channel region of one of the plurality of the first transistors has a first channel length, a channel region of one of the plurality of the second transistors has a second channel length, and the first arrangement is different from the second arrangement in that the first channel length and the second channel length are different.

11. The electronic device according to claim 10, wherein the first channel length is larger than the second channel length.

12. The electronic device according to claim 1, wherein a channel region of one of the plurality of the first transistors has a first channel area, a channel region of one of the plurality of the second transistors has a second channel area, and the first arrangement is different from the second arrangement in that the first channel area and the second channel area are different.

13. The electronic device according to claim 12, wherein the first area is larger than the second area.

14. The electronic device according to claim 1, wherein a channel region of one of the plurality of the first transistors has a first virtual diagonal, a channel region of one of the plurality of the second transistors has a second virtual diagonal, and the first arrangement is different from the second arrangement in that the first virtual diagonal is not parallel to the second virtual diagonal.

15. The electronic device according to claim 1, wherein the second region comprises a curved surface.

16. The electronic device according to claim 1, further comprising a conductive line electrically connected to the second driving circuit unit, wherein the first region comprises a flat portion, the second region comprises an opening portion and an arc portion, and the opening portion is between the flat portion and the arc portion, wherein the conductive line is disposed on the arc portion.

17. The electronic device according to claim 1, further comprising a gate driving circuit electrically connected to the second driving circuit unit, wherein the first region comprises a flat portion, the second region comprises an opening portion and an arc portion, and the opening portion is between the flat portion and the arc portion, wherein the gate driving circuit is disposed on the arc portion.

18. The electronic device according to claim 1, further comprising a sensing line, wherein the first region comprises a flat portion, the second region comprises an opening portion and an arc portion, and the opening portion is between the flat portion and the arc portion, wherein the sensing line is disposed on the flat portion and the arc portion.

19. The electronic device according to claim 1, wherein the second region comprises a plurality of openings and one of the plurality of openings is closer to the first region than another one of the plurality of openings, and an area of the one of the plurality of openings is larger than an area of the another one of the plurality of openings.
